(19) United States
(12) Patent Application Publication
(10) Pub. No.: US 2021/0343581 A1
(43) Pub. Date: Nov. 4, 2021

(54) SEMICONDUCTOR STRUCTURE AND METHOD FOR FORMING SAME

(71) Applicant: CHANGXIN MEMORY TECHNOLOGIES, INC., Hefei City (CN)

(72) Inventor: Hongmin WU, Hefei (CN)

(21) Appl. No.: 17/373,885

(22) Filed: Jul. 13, 2021

Related U.S. Application Data
(63) Continuation of application No. PCT/CN2021/082015, filed on Mar. 22, 2021.

(30) Foreign Application Priority Data
Apr. 9, 2020 (CN) 202010273298.9

(51) Int. Cl. H01L 21/768; H01L 23/535

(52) U.S. Cl. CPC H01L 21/7687; H01L 21/76823; H01L 27/10805; H01L 23/535; H01L 21/76832

(57) ABSTRACT

This disclosure relates to the technical field of semiconductor manufacturing, and discloses a semiconductor structure and a method for forming the same. The method includes: providing a semiconductor substrate having a plurality of contact structures arranged at an interval on a surface thereof, and the contact structures protruding from the substrate; forming a first dielectric layer on a side wall of the contact structure; depositing a second dielectric layer on surfaces of the semiconductor substrate, the contact structure and the first dielectric layer; enabling the first dielectric layer to react with the second dielectric layer; and removing an unreacted portion of the second dielectric layer by etching.

### CROSS-REFERENCE TO RELATED APPLICATION

This application is a U.S. continuation application of International Application No. PCT/CN2021/082015, filed on Mar. 22, 2021, which claims priority to Chinese patent application No. 202010273298.9, filed on Apr. 9, 2020. International Application No. PCT/CN2021/082015 and Chinese patent application No. 202010273298.9 are incorporated herein by reference in their entireties.

### TECHNICAL FIELD

This disclosure relates to the technical field of semiconductor manufacturing, and specifically relates to a semiconductor structure and a method for forming the same.

### BACKGROUND

A Dynamic Random Access Memory (DRAM) is a commonly used semiconductor memory in computers, and is composed of many repeated memory units. Each of the memory units generally includes a capacitor and a transistor, a gate electrode of the transistor is connected with a word line, a drain electrode of the transistor is connected with a bit line, a source electrode of the transistor is connected with the capacitor, and the opening or closing of the transistor are controlled by voltage signals on the word line, so that the data information stored in the capacitor may be read through the bit line, or the data information may be written into the capacitor through the bit line for storage. The capacitor of the DRAM is electrically connected with a landing pad through a lower electrode thereof and forms an access path with the drain electrode of the transistor.

As the feature size of semiconductor integrated circuit device continues to decrease, the semiconductor manufacturing technology is required to continue to increase. The existing capacitor has a larger resistance at the contact area with the landing pad. If the cross-sectional area of a capacitor column or the area of the landing pad is increased to improve the contact resistance, and increase the capacitor offset space, this not only imposes extremely high requirements on the existing process technology and is very difficult to control, but also causes the risk of short-circuit between two adjacent capacitors. Therefore, at present, a technical problem that needs to be urgently solved is how to improve the structure of the existing landing pad by innovating and optimizing the process for manufacturing semiconductor to increase the contact area between the landing pad and the capacitor column, so as to increase the capacitor offset space and reduce the resistance between the existing capacitor and the landing pad without increasing the size of the capacitor column.

### SUMMARY

This disclosure aims to provide a semiconductor structure and a method for forming the same. By innovating and optimizing the process for manufacturing the semiconductor, the width of the side wall of the landing pad is increased, thereby increasing the top area of the landing pad to achieve the increase of the capacitor offset space.

In order to solve the above technical problem, this disclosure provides a method for forming a semiconductor structure, including the following operations.

A semiconductor substrate is provided, a surface of the semiconductor substrate has a plurality of contact structures arranged at an interval, and the contact structures protrude from the substrate.

A first dielectric layer is formed on a side wall of the contact structure.

A second dielectric layer is deposited on surfaces of the semiconductor substrate, the contact structure, and the first dielectric layer.

The first dielectric layer is reacted with the second dielectric layer.

An unreacted portion of the second dielectric layer is removed by etching.

Optionally, before the first dielectric layer is formed on the side wall of the contact structure, the method further includes: depositing a sacrificial layer in the interval between the contact structures.

Optionally, a step of forming the first dielectric layer on the side wall of the contact structures further includes: firstly, forming a first dielectric layer on the surface of the contact structure, and then, retaining the first dielectric layer on the side wall of the contact structure by etching.

Optionally, a material of the first dielectric layer is polysilicon, and a thickness of the first dielectric layer is 10 nm to 50 nm.

Optionally, a material of the second dielectric layer is at least one selected from cobalt, titanium, tungsten, and nickel-platinum alloy.

Optionally, the first dielectric layer and the second dielectric layer are subjected to a high-temperature annealing technology, and a material of side wall dielectric layer formed by a combination of the first dielectric layer and the second dielectric layer is a metal silicide.

Optionally, the sacrificial layer is removed by an incineration technology to form an isolation structure for exposing the surface and a middle section of the contact structure.

Optionally, a material of the sacrificial layer is at least one selected from carbon and a silicon-containing polymer compound.

Correspondingly, the technical solution of this disclosure further provides a semiconductor structure. The semiconductor structure includes:

a semiconductor substrate that has a plurality of contact structures arranged at an interval on a surface thereof;

the contact structures protruding from the substrate; and

a side wall dielectric layer formed based on the above-mentioned method for forming the semiconductor structure.

The disclosure has the advantages that compared with the existing technologies for manufacturing the semiconductor, this disclosure mainly aims at the innovation and optimization of the process for manufacturing the semiconductor to improve the shape of the current capacitor joint. By increasing the width of the side wall of the landing pad, the top area of the landing pad can be increased to achieve the increase of the capacitor offset space, reduce the resistance of capacitor contact, and prevent short-circuit between two adjacent capacitors caused by the high temperature diffusion of tungsten, thereby increasing the yield rate of semiconductor structures in the semiconductor manufacturing technology.

Correspondingly, the technical solution of this disclosure further provides a semiconductor structure. The semiconductor structure includes:

a semiconductor substrate that has a plurality of contact structures arranged at an interval on a surface thereof;

the contact structures protruding from the substrate; and

a side wall dielectric layer formed based on the above-mentioned method for forming the semiconductor structure.

Another advantage of the disclosure is that compared with the existing technologies for manufacturing the semiconductor, this disclosure mainly aims at the innovation and optimization of the process for manufacturing the semiconductor to improve the shape of the current capacitor joint. By increasing the width of the side wall of the landing pad, the top area of the landing pad can be increased. In addition, by a landing pad that is hollow at a middle section, a capacitor can be erected on the landing pad and configured to be connected with another capacitor so as to form a unique structure. The size of the landing pad determines the space in which the capacitor can be offset. Therefore, the effect of increasing the capacitor offset space can be achieved and the resistance of capacitor contact can be reduced, increasing the yield rate of semiconductor structures in the semiconductor manufacturing technology.

### BRIEF DESCRIPTION OF THE DRAWINGS

In order to clearly illustrate the examples of the disclosure, accompanying drawings required in examples of the disclosure will be further described below briefly. It is apparent that the drawings illustrated in the following description only show some examples of the disclosure. Those skilled in the art can also obtain other drawings according to these drawings without any creative work.

FIG. 1 to FIG. 6 schematically show structures obtained by each of the steps sequentially implemented in a method for forming a semiconductor structure according to an example of this disclosure.

FIG. 7 to FIG. 14 schematically show structures obtained by each of the steps sequentially implemented in a method for forming a semiconductor structure according to another example of this disclosure.

### LIST OF REFERENCE SYMBOLS

100: semiconductor substrate; 200: contact structure; 201: first dielectric layer; 201a, 201b: side wall dielectric layer; 101: second dielectric layer; 300: sacrificial layer

### DETAILED DESCRIPTION

In order to make the objects, technical means and effects of this disclosure clearer, this application will be further elaborated below in conjunction with the drawings. It should be understood that the examples described here are only a part of the examples than all of the examples of this disclosure, and are not intended to limit this disclosure. Based on the examples of this disclosure, other examples obtained by those skilled in the art without creative efforts all fall within the protection scope of this disclosure.

At step 1, a semiconductor substrate 100 is provided. A surface of the semiconductor substrate 100 has a plurality of contact structures 200 arranged at an interval, and the contact structures 200 protrude from the semiconductor substrate 100.

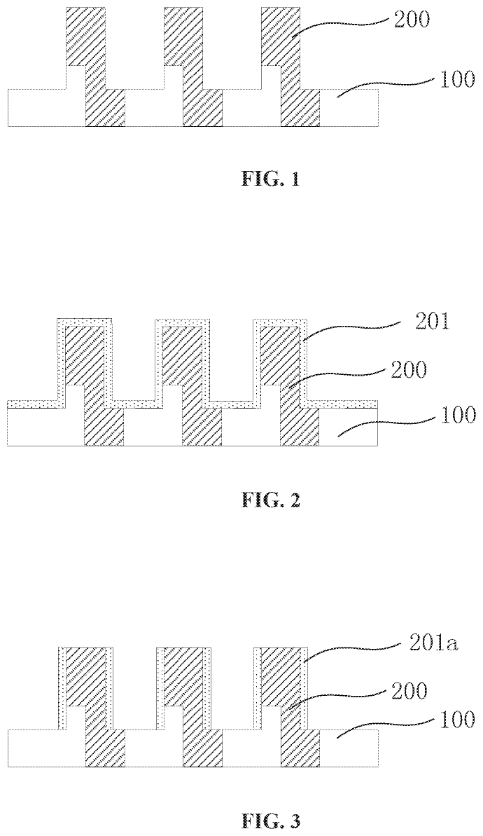

Referring to FIG. 1, the semiconductor substrate 100 is provided. The semiconductor substrate 100 may include, but is not limited to, a single crystal silicon substrate, a polysilicon substrate, a gallium nitride substrate or a sapphire substrate. In addition, when the semiconductor substrate 100 is a single crystal substrate or a polycrystalline substrate, the semiconductor substrate 100 may also be an intrinsic silicon substrate or a doped silicon substrate. Further, the semiconductor substrate 100 may be an N-type polysilicon substrate or a P-type polysilicon substrate.

The surface of the semiconductor substrate 100 has the plurality of contact structures 200 arranged at the interval. Each of the contact structures 200 passes through the surface of the semiconductor substrate 100, and the contact structure 200 may be, but is not limited to, related integrated circuit conductive materials such as tungsten, copper and the like.

At step 2, referring to FIG. 2, a first dielectric layer 201 is formed on the surface of the contact structure 200.

Specifically, the first dielectric layer 201 is formed on surfaces of the semiconductor substrate 100 and the contact structure 200. Those skilled in the art can understand that in a film deposition technology, there are two main deposition modes, i.e., chemical vapor deposition being a growth technology in which one or several substances in form of gas is activated in a certain mode to generate a chemical reaction and deposit a required solid film on the surface of the substrate; and physical vapor deposition being a technology that uses a certain physical process to realize the transfer of substances, e.g., transferring atoms or molecules to the surface of the silicon substrate and depositing a film thereon. The film deposition technology also includes a spin-coating method, an electroplating method, etc.

In this example, various deposition modes can be used for the first dielectric layer 201. For example, the chemical vapor deposition is used to deposit the first dielectric layer 201 with a preset thickness distribution on the surface of the semiconductor substrate 100 and the surface of the contact structure 200. Specifically, the control means of controlling the flow rate of the introduced gas, controlling the flow of the introduced gas, controlling the deposition time, or controlling the deposition temperature can be used alone to improve the control accuracy of the gasflow and temperature, thereby ensuring that all atoms are arranged neatly during deposition and finally the first dielectric layer 201 with a uniform thickness is formed on the surfaces of the semiconductor substrate 100 and the etched contact structure 200.

Commonly used deposition materials include single crystal silicon, polysilicon, silicon dioxide, silicon nitride, and insulating materials for isolating interconnection layers. In this example, the material of the first dielectric layer 201 is polysilicon, and the thickness of the first dielectric layer 201 is 10 nm to 50 nm.

At step 3, referring to FIG. 3, only the side wall dielectric layer 201a of the contact structure 200 is retained by dry etching.

There are two basic etching technologies in semiconductor manufacturing: dry etching and wet etching. The dry etching is a technical process in which the plasma is generated by gas ionization and performs physical and chemical reactions with the silicon wafer exposed to the plasma via a masking layer window formed by photoetching, so as to etch away the exposed surface material on the silicon wafer. The dry etching is used in fine etching of small feature sizes in advanced circuits. The dry etching refers to an etching technology in which gas is used as a main medium, the semiconductor material does not require liquid chemicals or flushing, and the semiconductor material can enter and exit the system in a dry state. Compared with the wet etching, the dry etching exhibits chemical isotropy (referring to the presence of etching in both longitudinal and horizontal directions) and physical anisotropy (referring to the presence of single longitudinal etching) in etching characteristics.

Specifically, in this example, the first dielectric layer 201 can be etched by the dry etching technology, and only the side wall dielectric layer 201a of the contact structure 200 is retained. The specific steps are as follows. The above-mentioned semiconductor structure is placed to a reaction chamber, and the pressure inside the chamber is reduced by a vacuum system. After the vacuum is established, the reaction chamber is filled with a reaction gas. For the etching of the material of the dielectric layer, the reaction gas generally uses other fluorine-containing gases as the etching gas, such as carbon tetrafluoride, sulfur hexafluoride and nitrogen trifluoride. A power source creates a radio frequency electric field through electrodes in the reaction chamber. The energy field excites the mixed gas into a plasma state. In the excited state, the reactive fluorine is etched and converted into volatile components to be discharged by the vacuum system.

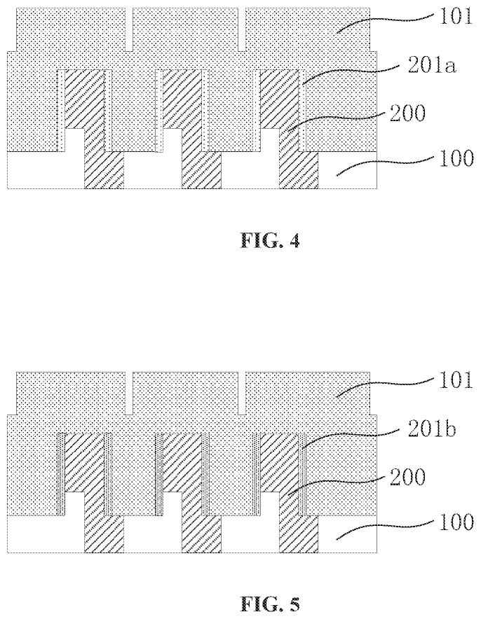

At step 4, referring to FIG. 4, a second dielectric layer 101 is deposited on the surfaces of the semiconductor substrate 100, the contact structure 200 and the side wall dielectric layer 201a.

Specifically, after the side wall dielectric layer 201a is formed on the surface of the contact structure 200, the second dielectric layer 101 is sequentially deposited on the surface of the semiconductor substrate 100, the surface of the side wall dielectric layer 201a and the surface of the contact structure 200 by a deposition technology.

The material of the second dielectric layer 101 includes cobalt, titanium, tungsten, nickel-platinum alloy, and the like. In this example, an electroplating ECP technology can be used for forming the second dielectric layer 101 on the surface of the semiconductor substrate 100, the surface of the side wall dielectric layer 201a and the surface of the contact structure 200.

At step 5, referring to FIG. 5, the second dielectric layer 101 and the side wall dielectric layer 201a are subjected to a high-temperature annealing technology, and the material of the side wall dielectric layer 201b formed by the combination of the second dielectric layer 101 and the side wall dielectric layer 201a is a metal silicide. Further, there are many methods for forming the metal silicide, high-temperature annealing is only one of the methods, which is not limited in this disclosure.

For example, the material of the second dielectric layer 101 may be cobalt. The material of the side wall dielectric layer 201b obtained thereby is a cobalt silicide. The material of the above-mentioned side wall dielectric layer 201b may be a metal silicide. The cobalt silicide has advantages of simple technology, good high temperature stability and the like, so the cobalt silicide as a substitute for the titanium silicide, was first applied to technology nodes ranging from 0.18 μm to 90 nm, mainly due to the fact that the cobalt silicide does not exhibit a line broadening effect under this size condition. In addition, the annealing temperature during the formation of the cobalt silicide is reduced compared with that of the titanium silicide, which is favorable for reducing the thermal budget of the technology and also improving the electric leakage and short-circuit caused by bridge connection. As for the high-temperature annealing technology, methods such as physical sputtering are used to deposit cobalt on a wafer, and then a first annealing at a lower temperature (600° C. to 700° C.) and a second annealing at a higher temperature (800° C. to 900° C.) are performed.

In this example, the metal silicide has a high melting point, high hardness, high-temperature chemical stability and excellent thermal conductivity and electrical conductivity, so that the metal silicide is suitable for the fields of high temperature resistance and wear resistance. It can prevent two adjacent capacitors from being short-circuited due to high temperature diffusion between the contact structures 200, thereby increasing the yield rate of semiconductor structures in the semiconductor manufacturing technology.

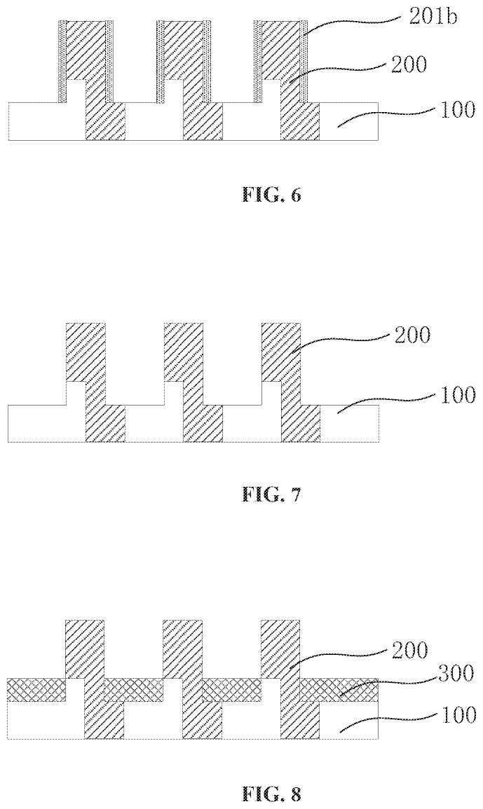

At step 6, referring to FIG. 6, an unreacted portion of the second dielectric layer 101 is removed by etching.

In this example, the second dielectric layer 101 on the surfaces of the contact structure 200 and the semiconductor substrate 100 may be etched away by a wet etching technology, and only the side wall dielectric layer 201b are retained. Since the material of the second dielectric layer 101 is a metal, diluted hydrofluoric acid is used for etching. In this example, using the wet etching can obtain accurate etching patterns, and also better control the retention of the side wall dielectric layer 201b, so as to prepare for the subsequent steps.

In this example, the combination of the contact structure 200 and the side wall dielectric layer 201a or the side wall dielectric layer 201b is defined as the landing pad. This example aims to improve the shape of the current capacitor joint. By increasing the width of the side wall of the landing pad, the top area of the landing pad can be increased to achieve the effect of increasing the capacitor offset space, reduce the resistance of capacitor contact, and prevent short-circuit between two adjacent capacitors caused by the high temperature diffusion of tungsten, thereby increasing the yield rate of semiconductor structures in the semiconductor manufacturing technology.

This disclosure further provides a semiconductor structure. Referring to FIG. 6, a schematic cross-sectional diagram of the semiconductor structure according to the above-mentioned example of this disclosure is shown.

The semiconductor structure includes a semiconductor substrate 100, contact structures 200 and a side wall dielectric layer 201b.

The semiconductor substrate 100 may include, but is not limited to, a single crystal silicon substrate, a polysilicon substrate, a gallium nitride substrate or a sapphire substrate. In addition, when the semiconductor substrate 100 is a single crystal substrate or a polycrystalline substrate, the semiconductor substrate 100 may also be an intrinsic silicon substrate or a doped silicon substrate. Further, the semiconductor substrate 100 may be an N-type polysilicon substrate or a P-type polysilicon substrate.

The surface of the semiconductor substrate 100 has the plurality of contact structures 200 arranged at the interval. Each of the contact structures 200 passes through the surface of the semiconductor substrate 100, and the contact structure 200 may be, but is not limited to, related integrated circuit conductive materials such as tungsten, copper and the like.

The side wall dielectric layer 201b is formed by the above-mentioned method for forming the semiconductor structure. The material of the side wall dielectric layer 201b is a metal silicide.

In this example, the metal silicide has a high melting point, high hardness, high-temperature chemical stability and excellent thermal conductivity and electrical conductivity, so that the metal silicide is suitable for the fields of high temperature resistance and wear resistance. This can prevent two adjacent capacitors from being short-circuited due to high temperature diffusion between the contact structures 200, thereby increasing the yield rate of semiconductor structures in the semiconductor manufacturing technology. In this example, the combination of the contact structure 200 and the side wall dielectric layer 201a or the side wall dielectric layer 201b is defined as the landing pad.

Further, the structural design of the side wall dielectric layer 201b can improve the shape of the current capacitor joint. By increasing the width of the side wall of the landing pad, the top area of the landing pad can be increased to achieve the effect of increasing the capacitor offset space, reduce the resistance of capacitor contact, and prevent short-circuit between two adjacent capacitors caused by the high temperature diffusion of tungsten, thereby increasing the yield rate of semiconductor structures in the semiconductor manufacturing technology.

This disclosure further provides another method for forming a semiconductor structure, which will be described in detail below with reference to the accompanying drawings and examples.

At step 1, a semiconductor substrate 100 is provided. A surface of the semiconductor substrate 100 has a plurality of contact structures 200 arranged at an interval, and the contact structures 200 protrude from the semiconductor substrate 100.

Referring to FIG. 7, the semiconductor substrate 100 is provided. The semiconductor substrate 100 may include, but is not limited to, a single crystal silicon substrate, a polysilicon substrate, a gallium nitride substrate or a sapphire substrate. In addition, when the semiconductor substrate 100 is a single crystal substrate or a polycrystalline substrate, the semiconductor substrate 100 may also be an intrinsic silicon substrate or a doped silicon substrate. Further, the semiconductor substrate 100 may be an N-type polysilicon substrate or a P-type polysilicon substrate.

The surface of the semiconductor substrate 100 has the plurality of contact structures 200 arranged at the interval, Each of the contact structures 200 passes through the surface of the semiconductor substrate 100, and the contact structure 200 may be, but is not limited to, related integrated circuit conductive materials such as tungsten, copper and the like.

At step 2, referring to FIG. 8, a sacrificial layer 300 is deposited on the interval of the contact structures 200.

Specifically, in this example, the sacrificial layer 300 is covered the interval of the contact structures 200 on the surface of the semiconductor substrate 100. The material of the sacrificial layer 300 includes spin-coated carbon or a silicon-containing polymer compound.

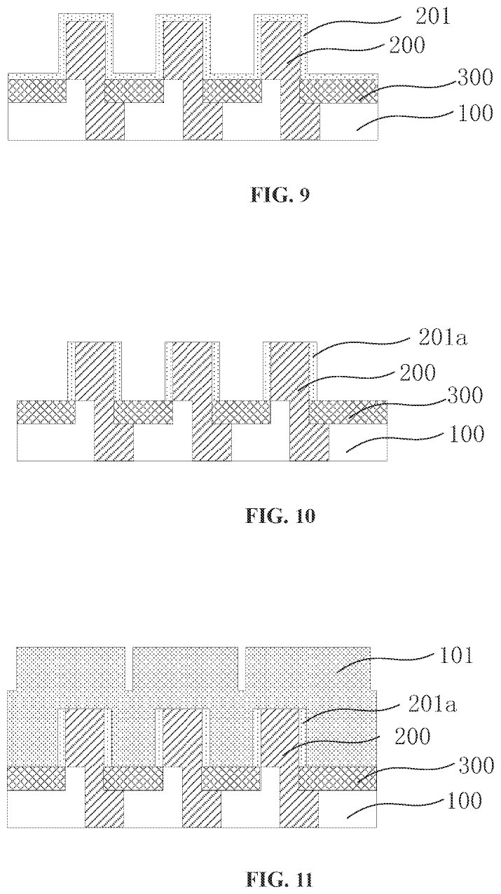

At step 3, referring to FIG. 9, a first dielectric layer 201 is formed on the surface of the contact structure 200.

Specifically, the first dielectric layer 201 is formed on the surfaces of the sacrificial layer 300 and the contact structure 200. Those skilled in the art can understand that in a film deposition technology, there are two main deposition modes, i.e., chemical vapor deposition being a growth technology in which one or several substances in form of gas is activated in a certain mode to generate a chemical reaction and deposit a required solid film on the surface of the substrate; and physical vapor deposition being a technology that uses a certain physical process to realize the transfer of substances, e.g., transferring atoms or molecules to the surface of the silicon substrate and depositing a film thereon. The film deposition technology also includes a spin-coating method, an electroplating method, etc.

In this example, various deposition modes can be used for the first dielectric layer 201. For example, the chemical vapor deposition is used to deposit the first dielectric layer 201 with preset thickness distribution on the surface of the sacrificial layer 300 and the surface of the contact structure 200. Specifically, the control means of controlling the flow rate of the introduced gas, controlling the flow of the introduced gas, controlling the deposition time, or controlling the deposition temperature can be used alone to improve the control accuracy of the gasflow and temperature, thereby ensuring that all atoms are arranged neatly during deposition, and finally the first dielectric layer 201 with a uniform thickness is formed on the surfaces of the sacrificial layer 300 and the etched contact structure 200.

Commonly used deposition materials include single crystal silicon, polysilicon, silicon dioxide, silicon nitride, and insulating materials for isolating interconnection layers. In this example, the material of the first dielectric layer 201 is polysilicon, and the thickness of the first dielectric layer 201 is 10 nm to 50 nm.

At step 4, referring to FIG. 10, only side wall dielectric layer 201a of the contact structure 200 is retained by dry etching.

There are two basic etching technologies in semiconductor manufacturing: dry etching and wet etching. The dry etching is a technical process in which the plasma is generated by gas ionization and performs physical and chemical reactions with the silicon wafer exposed to the plasma via a masking layer window formed by photoetching, so as to etch away the exposed surface material on the silicon wafer. The dry etching is used in fine etching of small feature sizes in advanced circuits. The dry etching refers to an etching technology in which gas is used as a main medium, the semiconductor material does not require liquid chemicals or flushing, and the semiconductor material can enter and exit the system in a dry state. Compared with the wet etching, the dry etching exhibits chemical isotropy (referring to the presence of etching in both longitudinal and horizontal directions) and physical anisotropy (referring to the presence of single longitudinal etching) in etching characteristics.

Specifically, in this example, the first dielectric layer 201 can be etched by the dry etching technology, and only the side wall dielectric layer 201a of the contact structure 200 is retained. The specific steps are as follows. The above-mentioned semiconductor structure is placed to a reaction chamber, and the pressure inside the chamber is reduced by a vacuum system. After the vacuum is established, the reaction chamber is filled with a reaction gas. For the etching of the material of the dielectric layer, the reaction gas generally uses other fluorine-containing gases as the etching gas, such as carbon tetrafluoride, sulfur hexafluoride and nitrogen trifluoride. A power source creates a radio frequency electric field through electrodes in the reaction chamber. The energy field excites the mixed gas into a plasma state. In the excited state, the reactive fluorine is etched and converted into volatile components to be discharged by the vacuum system.

At step 5, referring to FIG. 11, a second dielectric layer 101 is deposited on the surfaces of the sacrificial layer 300, the contact structure 200 and the side wall dielectric layer 201a.

Specifically, after the side wall dielectric layer 201a is formed on the surface of the contact structure 200, the second dielectric layer 101 is sequentially deposited on the surface of the sacrificial layer 300, the surface of the side wall dielectric layer 201a and the surface of the contact structure 200 by a deposition technology.

The material of the second dielectric layer 101 includes cobalt, titanium, tungsten, nickel-platinum alloy and the like. In this example, an electroplating ECP technology can be used for forming the second dielectric layer 101 on the surface of the sacrificial layer 300, the surface of the side wall dielectric layer 201a and the surface of the contact structure 200.

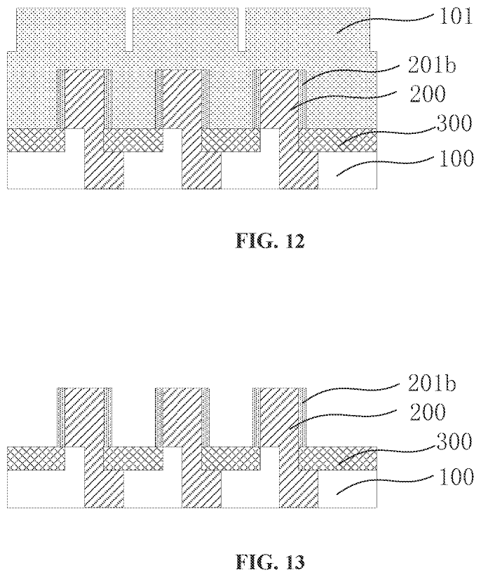

At step 6, referring to FIG. 12, the second dielectric layer 101 and the side wall dielectric layer 201a are subjected to a high-temperature annealing technology, and the material of the side wall dielectric layer 201b formed by the combination of the second dielectric layer 101 and the side wall dielectric layer 201a is a metal silicide. Further, there are many methods for forming the metal silicide, high temperature annealing is only one of the methods, which is not limited in this disclosure.

For example, the material of the second dielectric layer 101 may be cobalt. The material of the side wall dielectric layer 201b obtained thereby is a cobalt silicide. The material of the above-mentioned side wall dielectric layer 201b may be a metal silicide. The cobalt silicide has advantages of simple technology, good high temperature stability and the like, so the cobalt silicide as a substitute for the titanium silicide, was first applied to technology nodes ranging from 0.18 μm to 90 nm, mainly due to the fact that the cobalt silicide does not exhibit a line broadening effect under this size condition. In addition, the annealing temperature during the formation of the cobalt silicide is reduced compared with that of the titanium silicide, which is favorable for reducing the thermal budget of the technology and also improving the electric leakage and short-circuit caused by bridge connection. As for the high-temperature annealing technology, methods such as physical sputtering are used to deposit cobalt on a wafer, and then a first annealing at a lower temperature (600° C. to 700° C.) and a second annealing at a higher temperature (800° C. to 900° C.) are performed.

In this example, the metal silicide has a high melting point, high hardness, high-temperature chemical stability and excellent thermal conductivity and electrical conductivity, so that the metal silicide is suitable for the fields of high temperature resistance and wear resistance. It can prevent two adjacent capacitors from being short-circuited due to high temperature diffusion between the contact structures 200, thereby increasing the yield rate of semiconductor structures in the semiconductor manufacturing technology.

At step 7, referring to FIG. 13, an unreacted portion of the second dielectric layer 101 is removed by etching.

In this example, the second dielectric layer 101 on the surfaces of the contact structure 200 and the semiconductor substrate 100 may be etched away by a wet etching technology, and the side wall dielectric layer 201b and the sacrificial layer 300 are retained. Since the material of the second dielectric layer 101 is a metal, diluted hydrofluoric acid is used for etching. In this example, using the wet etching can obtain accurate etching patterns, and also better control the retention of the side wall dielectric layer 201b, so as to prepare for the subsequent steps.

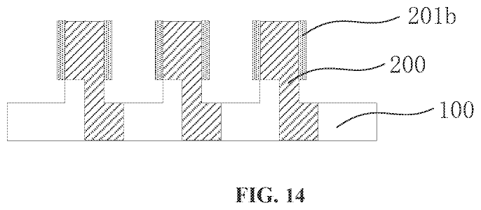

At step 8, referring to FIG. 14, the sacrificial layer 300 is removed to form an isolation structure exposing the surface and middle section of the contact structure 200.

Specifically, the sacrificial layer 300 is removed by an incineration technology to form the isolation structure exposing the surface and middle section of the contact structure 200.

In this example, the combination of the contact structure 200 and the side wall dielectric layer 201a or the side wall dielectric layer 201b is defined as the landing pad. Therefore, this example mainly aims at the innovation and optimization of the semiconductor manufacturing process to improve the shape of the current capacitor joint, so as to form a unique structure. By increasing the width of the side wall of the landing pad, the top area of the landing pad can be increased. By the landing pad that is hollow at a middle section, a capacitor can be erected on the landing pad and configured to be connected with another capacitor so as to form a unique structure. The size of the landing pad determines the space in which the capacitor can be offset. Therefore, the effect of increasing the capacitor offset space can be achieved, the resistance of capacitor contact can be reduced, and short-circuit between two adjacent capacitors caused high temperature diffusion of tungsten can be prevented, thereby increasing the yield rate of semiconductor structures in the semiconductor manufacturing technology.

This disclosure further provides a semiconductor structure. Referring to FIG. 14, a schematic cross-sectional diagram of a semiconductor structure according to another example of this disclosure is shown.

The semiconductor structure includes a semiconductor substrate 100, contact structures 200 and a side wall dielectric layer 201b.

The semiconductor substrate 100 may include, but is not limited to, a single crystal silicon substrate, a polysilicon substrate, a gallium nitride substrate or a sapphire substrate. In addition, when the semiconductor substrate 100 is a single crystal substrate or a polycrystalline substrate, the semiconductor substrate 100 may also be an intrinsic silicon substrate or a doped silicon substrate. Further, the semiconductor substrate 100 may be an N-type polysilicon substrate or a P-type polysilicon substrate.

The surface of the semiconductor substrate 100 has the plurality of contact structures 200 arranged at the interval. Each of the contact structures 200 passes through the surface of the semiconductor substrate 100, and the contact structure 200 may be, but is not limited to, related integrated circuit conductive materials such as tungsten, copper and the like.

The side wall dielectric layer 201b is formed by the above-mentioned method for forming the semiconductor structure. The material of the side wall dielectric layer 201b is a metal silicide.

In this example, the metal silicide has a high melting point, high hardness, high-temperature chemical stability and excellent thermal conductivity and electrical conductivity, so that the metal silicide is suitable for the fields of high temperature resistance and wear resistance. This can prevent two adjacent capacitors from being short-circuited due to high temperature diffusion between the contact structures 200, thereby increasing the yield rate of semiconductor structures in the semiconductor manufacturing technology. In this example, the combination of the contact structure 200 and the side wall dielectric layer 201a or the side wall dielectric layer 201b is defined as the landing pad.

Further, the structural design of the side wall dielectric layer 201b can increase the width of the side wall, thereby increasing the top area of the landing pad.

Further, by the landing pad that is hollow at a middle section, a capacitor can be erected on the landing pad and configured to be connected with another capacitor so as to form a unique structure. The size of the landing pad determines the space in which the capacitor can be offset. Therefore, the effect of increasing the capacitor offset space can be achieved, the resistance of capacitor contact can be reduced, and short-circuit between two adjacent capacitors caused high temperature diffusion of tungsten can be prevented, thereby increasing the yield rate of the semiconductor structure in the semiconductor manufacturing technology.

The above examples are only preferred examples of this application. It should be noted that those skilled in the art can make several improvements and modifications without departing from the principles of this application, and these improvements and modifications should also be regarded as within the protection scope of this application.

1. A method for forming a semiconductor structure, comprising:
providing a semiconductor substrate, wherein a surface of the semiconductor substrate has a plurality of contact structures arranged at an interval, and the contact structures protrude from the semiconductor substrate;
forming a first dielectric layer on a side wall of the contact structure;
depositing a second dielectric layer on a surface of the semiconductor substrate, a surface of the contact structure and a surface of the first dielectric layer;
enabling the first dielectric layer to react with the second dielectric layer; and
removing an unreacted portion of the second dielectric layer by etching.

2. The method for forming the semiconductor structure of claim 1, wherein a step of forming the first dielectric layer on the side wall of the contact structure further comprises: firstly, forming the first dielectric layer on the surface of the contact structure, and then, retaining the first dielectric layer on the side wall of the contact structure by etching.

3. The method for forming the semiconductor structure of claim 1, wherein a material of the first dielectric layer is polysilicon, and a thickness of the first dielectric layer is 10 nm to 50 nm.

4. The method for forming the semiconductor structure of claim 1, wherein a material of the second dielectric layer is at least one selected from cobalt, titanium, tungsten and nickel-platinum alloy.

5. The method for forming the semiconductor structure of claim 1, wherein the first dielectric layer and the second dielectric layer are subjected to a high-temperature annealing technology, and a material of a side wall dielectric layer formed by a combination of the first dielectric layer and the second dielectric layer is a metal silicide.

6. The method for forming the semiconductor structure of claim 1, wherein the method further comprises before forming the first dielectric layer on the side wall of the contact structure, depositing a sacrificial layer between the interval of the contact structures.

7. The method for forming the semiconductor structure of claim 6, wherein the method further comprises removing the sacrificial layer by an incineration technology to form an isolation structure exposing the surface and a middle section of the contact structure.

8. The method for forming the semiconductor structure of claim 6, wherein a material of the sacrificial layer is at least one selected from carbon and a silicon-containing polymer compound.

9. A semiconductor structure, comprising:
a semiconductor substrate, wherein a surface of the semiconductor substrate has a plurality of contact structures arranged at an interval;
contact structures protruding from the semiconductor substrate; and
a side wall dielectric layer formed by the method for forming the semiconductor structure of claim 1.

10. A semiconductor structure, comprising:
a semiconductor substrate, wherein a surface of the semiconductor substrate has a plurality of contact structures arranged at an interval;
contact structures protruding from the semiconductor substrate; and
a side wall dielectric layer formed by the method for forming the semiconductor structure of claim 2.

11. A semiconductor structure, comprising:
a semiconductor substrate, wherein a surface of the semiconductor substrate has a plurality of contact structures arranged at an interval;
contact structures protruding from the semiconductor substrate; and
a side wall dielectric layer formed by the method for forming the semiconductor structure of claim 3.

12. A semiconductor structure, comprising:
a semiconductor substrate, wherein a surface of the semiconductor substrate has a plurality of contact structures arranged at an interval;
contact structures protruding from the semiconductor substrate; and
a side wall dielectric layer formed by the method for forming the semiconductor structure of claim 4.

13. A semiconductor structure, comprising:
a semiconductor substrate, wherein a surface of the semiconductor substrate has a plurality of contact structures arranged at an interval;
contact structures protruding from the semiconductor substrate; and
a side wall dielectric layer formed by the method for forming the semiconductor structure of claim 5.

14. A semiconductor structure, comprising:
a semiconductor substrate, wherein a surface of the semiconductor substrate has a plurality of contact structures arranged at an interval;
contact structures protruding from the semiconductor substrate; and
a side wall dielectric layer formed by the method for forming the semiconductor structure of claim 6.

15. A semiconductor structure, comprising:
a semiconductor substrate, wherein a surface of the semiconductor substrate has a plurality of contact structures arranged at an interval;
contact structures protruding from the semiconductor substrate; and
a side wall dielectric layer formed by the method for forming the semiconductor structure of claim 7.

16. A semiconductor structure, comprising:
a semiconductor substrate, wherein a surface of the semiconductor substrate has a plurality of contact structures arranged at an interval;
contact structures protruding from the semiconductor substrate; and
a side wall dielectric layer formed by the method for forming the semiconductor structure of claim 8.
